(19) United States
(12) Patent Application Publication
(10) Pub. No.: US 2006/0073702 A1
(43) Pub. Date: Apr. 6, 2006

(54) Memory structure and manufacturing as well as programming method thereof

(75) Inventor: Fuja Shone, Hsinchu (TW)

Correspondence Address: OLIFF & BERRIDGE, PLC, P.O. BOX 19928, ALEXANDRIA, VA, 22320, US

(73) Assignee: Skymedi Corporation, Hsinchu (TW)

(21) Appl. No.: 10/944,903

(22) Filed: Sep. 21, 2004

(51) Int. Cl. H01L 21/44

(52) U.S. Cl. 438/672

(57) ABSTRACT

A memory structure includes a floating gate and a nitride gate dielectric on a semiconductor substrate, wherein the floating gate and nitride gate dielectric function as two memory cells. In addition to the floating gate and nitride gate dielectric, the memory structure further comprises two bitlines and a select gate. The two bitlines are formed in the semiconductor substrate, the floating gate and the select gate are formed above the semiconductor substrate and transversely disposed between the two bitlines, and the nitride gate dielectric is formed between the select gate and the semiconductor substrate.

### BACKGROUND OF THE INVENTION

(A) Field of the Invention

The present invention is related to a non-volatile memory and a manufacturing method as well as a programming method thereof, and more specifically to a memory structure including a split gate and the relevant manufacturing and programming method thereof.

(B) Description of the Related Art

Non-volatile memory devices are currently in wide use in electronic components that require the retention of information when electrical power is terminated. Non-volatile memory devices include read only memory (ROM), programmable read only memory (PROM), erasable programmable read only memory (EPROM) and electrically erasable programmable read only memory (EEPROM) devices. EEPROM devices differ from other non-volatile memory devices in that they can be electrically programmed and erased. Flash EEPROM devices are similar to EEPROM devices in that memory cells can be programmed and erased electrically. However, flash EEPROM devices enable the erasing of all memory cells in the devices using a single electrical current pulse.

Typically, an EEPROM device includes a floating-gate electrode upon which electrical charge is stored. In a flash EEPROM device, electrons are transferred to a floating-gate electrode through a dielectric layer overlying the channel region of the transistor. The electron transfer is initiated by either hot electron injection or Fowler-Nordheim (F-N) tunneling.

In IEDM Conference 2002, Y. Sasago et al. disclosed a formation process of a split gate memory as shown in FIGS. 1(a) through 1(e), wherein U-shaped floating gates are used for reducing threshold voltage (Vth) shift. In FIG. 1(a), a gate oxide layer 11, a polysilicon layer 12 and a silicon oxide layer 13 are sequentially formed on a silicon substrate 10 and patterned by lithography and etching processes to form separated lines. In FIG. 1(b), oxide spacers 14 are formed by oxide deposition and etching, or thermal growth. Then, dopants such as arsenic ions are implanted with a tilted angle to form n+ regions 15. In FIG. 1(c), because doped silicon usually has a relatively high oxide growth rate in comparison with that of undoped silicon, a tunnel oxide layer 16 with a thicker portion 17 on the n+ regions 15 can be formed by thermal growth. Then, a polysilicon layer 18 is deposited, and polymer plugs 19 are deposited in the spaces between the polysilicon lines 12 as etch-back masks. In FIG. 1(d), the polysilicon layer 18 is etch-backed to be separated floating gates. In FIG. 1(e), the polymer plugs 19 are removed, and then an oxide/nitride/oxide (ONO) layer 20 and a polysilicon layer 21 are deposited. Then, the polysilicon layer 21 is patterned to be separated wordlines, i.e., control gates. Accordingly, in addition to the polysilicon layers 18 and polysilicon layer 21 function as floating gates and control gate respectively, the polysilicon lines 12 serve as select gates.

Referring to FIG. 2, U.S. Pat. No. 6,567,315 disclosed an operation method for a split gate memory cell, which can be applied to the memory cells disclosed by Sasago et al. Accordingly, the polysilicon layers 12, 18 and 21 described above are denoted by SG, FG and CG, and doping regions 15 act as source (S) and drain (D). Voltages of approximately 14V, 5V and 0.6V are applied to the control gate CG, drain D and select gate SG, respectively, and source S is grounded. Consequently, a depletion region is formed within the substrate and a drain current is generated thereby, and therefore hot electrons generated when a drain current flows from the source side to the drain side are injected into the floating gate FG for programming, that is, the so-called hot electron programming.

Moreover, Yamauchi et al. disclosed a process for forming a split gate memory cell in the International Conference on Solid State Devices and Materials, Yokohama, 1994. In FIG. 3(a), gate structures with a tunnel oxide layer 301, a floating gate 302, an ONO layer 303, a control gate 304 and a silicon dioxide layer 305 are formed on a substrate 30, and photoresist 306 is patterned to cap a portion of the substrate 30. Then, the substrate 30 uncovered by the photoresist 306 is implanted by dopants such as arsenic ions, so as to form a drain region 307. In FIG. 3(b), the photoresist 306 is stripped, a polysilicon layer 309 is deposited, and then silicon oxide spacers 310 are formed. Sequentially, another implantation is conducted to form source region 311. In FIG. 3(c), a tungsten silicide layer 312 is deposited after the silicon oxide spacers 310 are removed, and then the tungsten silicide layer 312 is etched to define the select gate.

Apparently, the above prior art references are either complex or limited to the operation by hot electron programming, so that an alternative process and operation method are needed to enhance the production efficiency and obtain better operation flexibility.

### SUMMARY OF THE INVENTION

The objective of the present invention is to provide a memory structure and a programming method as well as a manufacturing method thereof, so as to increase the cell integration, simplify the process and obtain more flexibility for operation.

To achieve the above objective, a memory structure including a floating gate and a nitride gate dielectric on a semiconductor substrate is disclosed, wherein the floating gate and nitride gate dielectric function as two memory cells. In addition to the floating gate and nitride gate dielectric, the memory structure further comprises two bitlines and a select gate. The two bitlines are formed in the semiconductor substrate, the floating gate and the select gate are formed above the semiconductor substrate and transversely disposed between the two bitlines, and the nitride gate dielectric is formed between the select gate and the semiconductor substrate.

The above memory structure can be manufactured by the following steps. First, a storage layer such as an ONO layer serving as the nitride gate dielectric is formed on the semiconductor substrate, followed by forming a first conductive line above the storage layer. Next, two doping regions serving as the bitlines are formed in a semiconductor substrate by tilted-implantation or mask spacer shielding. Then, at least one dielectric spacer is formed beside the first conductive line, and a first dielectric layer, a second conductive line, a second dielectric layer and a third conductive line are stacked sequentially. As a result, the dielectric spacer is between the first and second conductive lines for insulation, and the first, second and third conductive lines function as the select gate, floating gate and wordline, respectively.

Alternatively, a process for forming a floating gate first can also be employed. In comparison with the above process, the ONO layer beneath the first conductive line is replaced with a dielectric layer serving as tunnel oxide, and the first dielectric layer includes at least one nitride film as a storage layer. In contrast, the first and second conductive lines function as the floating gate and select gate, respectively.

For programming the floating gate within the memory structure mentioned above, a positive voltage is applied to the wordline so as to turn on the floating gate, and a negative voltage is applied to the bitline next to the floating gate, whereby a bias voltage across the dielectric layer is generated for programming the floating gate.

The method of the present invention uses F-N programming instead of hot electron programming. It provides an alternative operation method so that the more flexible operation for floating gate memory cells in this memory structure can be attained. Moreover, hot electron and F-N programming in nitride gate can be achieved, which increases the memory structure density significantly.

### BRIEF DESCRIPTION OF THE DRAWINGS

FIGS. 1(a) through 1(e) illustrate a known process for manufacturing split gate memory cells;

FIG. 2 illustrates a known hot electron programming method for a split gate memory cell;

FIGS. 3(a) through 3(c) illustrate another known process for manufacturing split gate memory cells;

FIGS. 4(a) through 4(f) illustrate the method for manufacturing the memory structure of the first embodiment in accordance with the present invention;

FIG. 4(g) illustrates the schematic diagram with reference to the memory cells as shown in FIG. 4(e) in accordance with the present invention;

FIGS. 5(a) through 5(f) illustrate the method for manufacturing the memory structure of the second embodiment in accordance with the present invention; and

FIG. 5(g) illustrates the schematic diagram with reference to the memory cells as shown in FIG. 5(e) in accordance with the present invention.

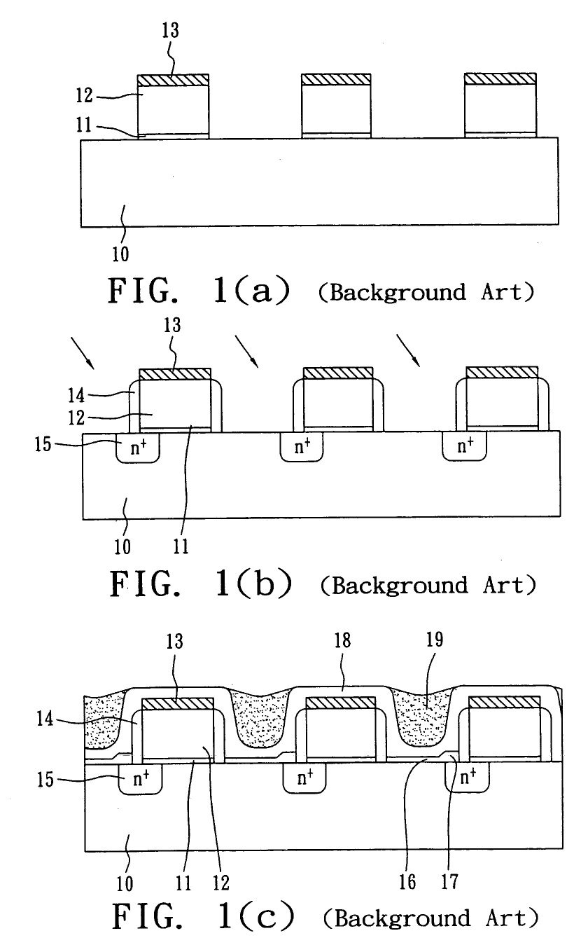

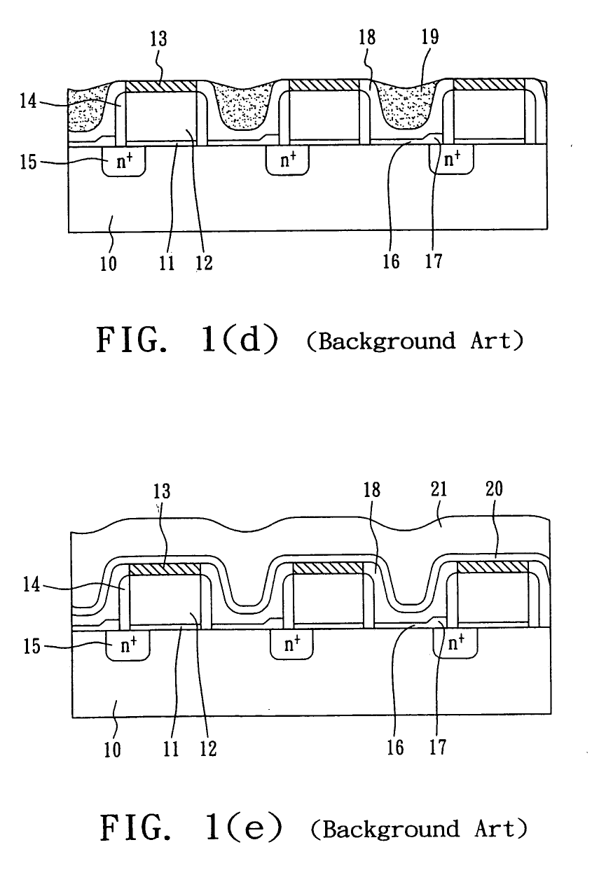

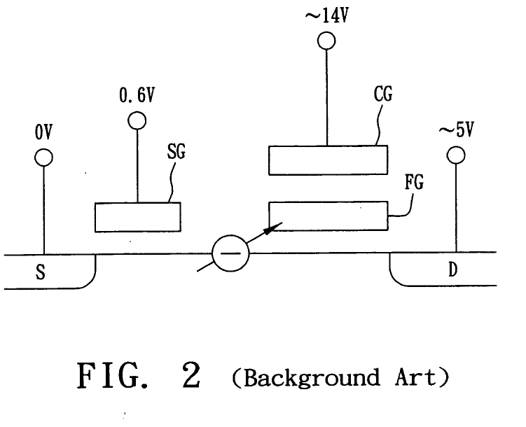

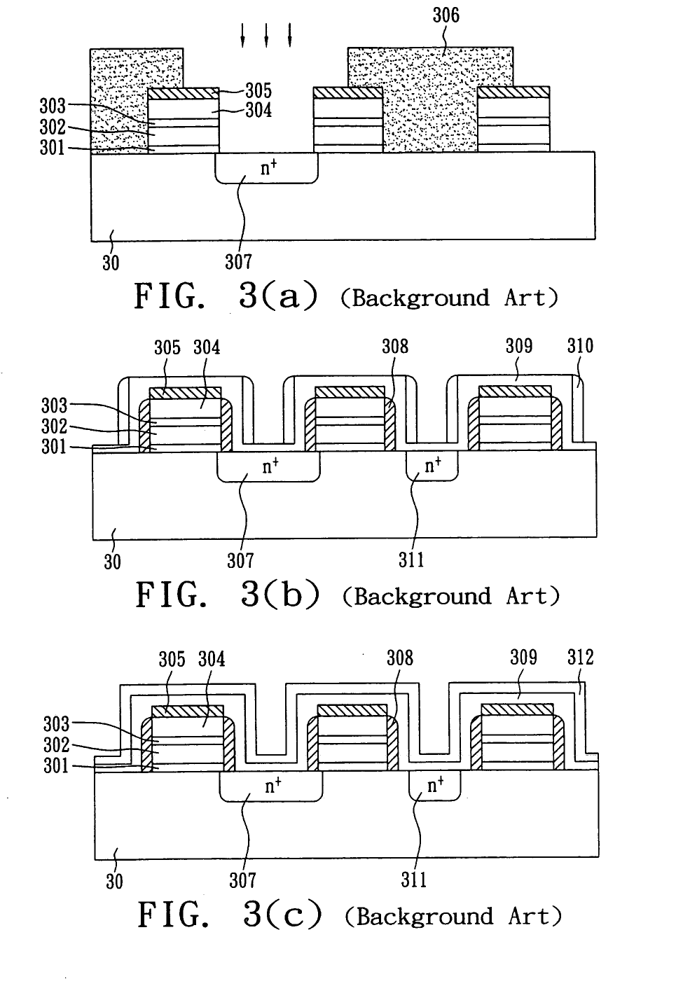

### DETAILED DESCRIPTION OF THE INVENTION

Embodiments of the present invention are now being described with reference to the accompanying drawings.

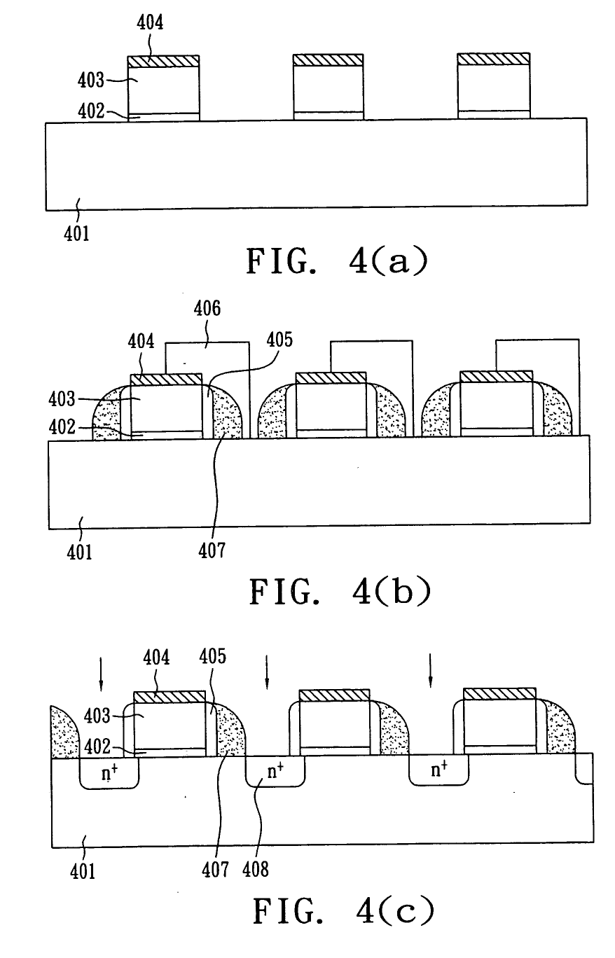

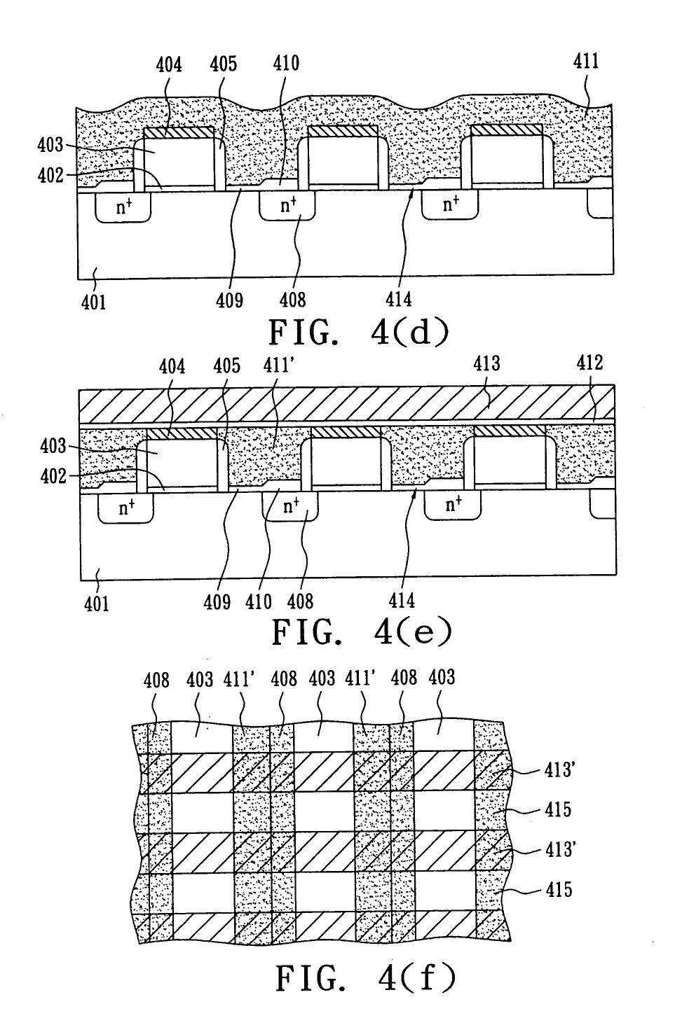

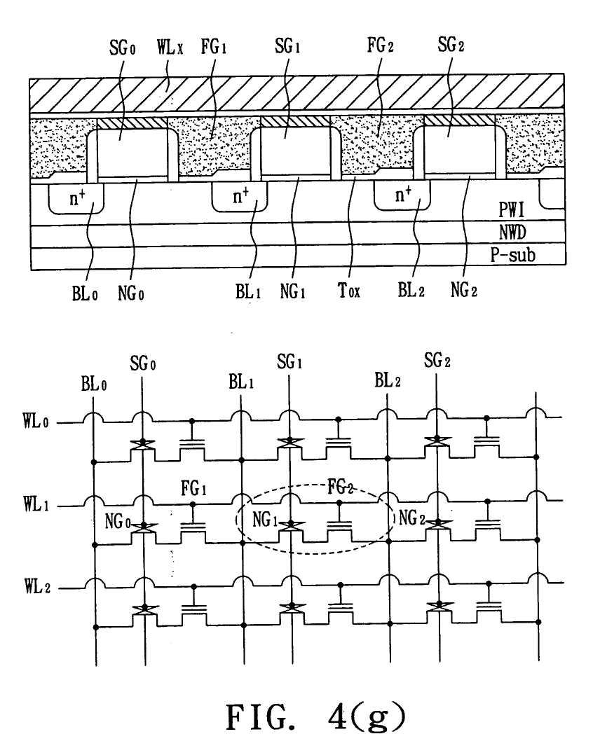

FIGS. 4(a) through 4(f) illustrate a process for forming the memory structure of the first embodiment in accordance with the present invention.

In FIG. 4(a), an ONO layer, a first conductive layer, an insulating layer are sequentially formed on a silicon substrate 401, and are patterned to be individual gate structures afterwards. Each gate structure comprises an ONO layer 402, a first conductive line 403 and an insulating layer 404. The first conductive line 403 may be composed of polysilicon, whereas the insulating layer 404 may be a multilayer of silicon nitride and silicon oxide. In FIG. 4(b), dielectric spacers 405 ranging from 100 to 300 angstroms and mask spacers 407, e.g., silicon nitride spacers, ranging from 200 to 800 angstroms are sequentially formed beside the first conductive lines 403. Then, photoresist is deposited and patterned as multiple photoresist caps 406 to cover one side mask spacer 407 of each first conductive line 403, and in consequence, as shown in FIG. 4(c), the uncovered nitride spacers 407 will be stripped away while being dipped in hot phosphoric acid, and the photoresist caps 406 are removed afterwards. Dopants such as arsenic ions are implanted with an energy between 5×10¹⁴ and 5×10¹⁵ atoms/cm² into the substrate 401 to form doping regions 408 serving as bitlines. In FIG. 4(d), the remaining nitride spacers 407 are dipped away, and then first dielectric layers 414 comprising tunnel oxides 409 and silicon oxide layers 410 are formed on the substrate 401 by thermal growth or deposition. In the case of thermal growth, because the growth rate of oxide on doped silicon is faster than that on undoped one, the oxide layer 410 is thicker than the tunnel oxide layer 409. For example, the thickness of the layer 409 is in the range between 100 to 300 angstroms, whereas the thickness of the layer 410 is in the range between 300 to 800 angstroms. It is intended to ensure that the tunneling effect occurs through the tunnel oxide layer 409 rather than the layer 410. Optionally, if the oxide layer 410 is not thick enough or the thickness ratio of the layers 410 and 409 fails to meet the criteria, the first dielectric layer 414 can be partially etched away and grown again to be of the desired thickness. Sequentially, a second conductive layer 411, e.g., a polysilicon layer, is deposited. In FIG. 4(e), the second conductive layer 411 is planarized to be separated second conductive lines 411′, followed by forming an ONO layer 412 and a third conductive layer 413 sequentially. FIG. 4(f) illustrates the top view of the memory array described above, in which the third conductive layer 413 is etched to be separated third conductive lines 413′ serving as wordlines, and oxide layers 415 are formed therebetween for insulation. The third conductive lines 413′ are perpendicular to the two doping regions 408. Accordingly, the first and second conductive lines 403 and 411′ function as a select gate and a floating gate, respectively, whereas the ONO layer 402 can be a storage layer to trap electrons, and can be named a nitride gate dielectric.

FIG. 4(g) illustrates a schematic diagram with reference to the memory structure of the first embodiment set forth in the present invention, in which the memory cell architecture is the same as that shown in FIG. 4(e) but some components are renamed according to their functionality, where a word line is denoted by WL, a bitline is denoted by BL, a select gate is denoted by SG, a floating gate is denoted by FG, a nitride gate memory cell is denoted by NG, and a tunnel oxide layer is denoted by Tox. Moreover, PWI and NWD wells are formed in the P-substrate. Examples for reading, programming and erasing the floating gate memory cell WL₁, BL₁, BL₂, i.e., FG₂ the one within dash line circle in FIG. 4(g), are shown in Table 1, assuming the threshold voltages for programming and erasing the floating gate memory cell are 2V and −1V, respectively. In addition, assuming the gate coupling ratios of the floating memory cells and nitride memory cells are 50% and 90%, respectively.

TABLE 1

| | WL₀ | WL₁ | WL₂ | SG₀ | SG₁ | SG₂ | BL₀ | BL₁ | BL₂ | PWI | NWD | P-sub |
|---|---|---|---|---|---|---|---|---|---|---|---|---|
| Program | 0 V | 12 V | 0 V | 0 V | −5 V | −5 V | 0 V | 0 V | −5 V | −5 V | 0.3 V | 0 V |
| Page | 0 V | −20 V | 0 V | 0 V | 0 V | 0 V | 0 V | 0 V | 0 V | 0 V | 0 V | 0 V |
| erase | 0 | −12 V | 0 V | 0 V | 0 V | 0 V | 5 V | 5 V | 5 V | 0 V | 0 V | 0 V |
| Bit/byte | 0 V | −12 V | 0 V | 0 V | 0 V | 0 V | 0 V | 0 V | 5 V | 0 V | 0 V | 0 V |
| erase | | | | | | | | | | | | |
| Read | 0 V | 3 V | 0 V | 0 V | 5 V | 0 V | 0 V | 0 V | 1.5 V | 0 V | 0 V | 0 V |

For programming, 12V is applied to WL₁, and −5V is applied to BL₂, thereby an effective high voltage bias is generated across the tunnel oxide layer Tox, so that electron can be injected into the floating gate FG₂, i.e., F-N programming occurs. In order to prevent bias voltage generation on the right hand side of the BL₂, −5V or more negative voltage is applied to SG₁ and SG₂. In other words, the voltage applied to the select gate next to the selected bitline is equal to or more negative in comparison with the bitline voltage, so that the select gate and the bitline are kept at equal potential to avoid that bitline voltage is transferred to another memory cell. Further, −5V is applied to PWI, 0.3V is applied to NWD, and P-substrate is grounded, such that equal potential or reverse bias occurs between n+ bitline and PWI, and PWI and NWD, and so occurs between NWD and P-sub.

For page erasure, i.e., erasing all the memory cells of a wordline, a high voltage such as −20V is applied to WL₁, so as to erase all the memory cells of WL₁ at the same time. Alternatively, voltages of 5V are applied to all the bitlines BL₀, BL₁ and BL₂, and are associated with that the −12V applied to the WL₁, thereby all the floating gate memory cells with reference to WL₁ can be erased.

For bit/byte erasure, a relatively low voltage compared to that for page erasure such as −12V is applied to WL₁, and such voltage cannot expel electrons out of the floating gates. In addition, 5V is applied to BL₂, and is associated with −12V to generate sufficient bias voltage for F-N tunneling erasure in respect of the cell FG₂. Accordingly, only FG₂ is erased.

For reading, WL₁, SG₁ and BL₂ are 3V, 5V and 1.5V, respectively. Accordingly, no current occurs if the FG₂ is programmed, and, in contrast, current occurs if the FG₂ is not programmed.

For reading, programming and erasing of the nitride gate memory cell WL₁, BL₁, BL₂, i.e., NG₁ the one within dash line circle in FIG. 4(g), are shown in Table 2. Assuming the threshold voltage for programming and erasing the nitride gate memory cell are 3.5V and 1.5V, respectively.

TABLE 2

| | WL₀ | WL₁ | WL₂ | SG₀ | SG₁ | SG₂ | BL₀ | BL₁ | BL₂ | PWI | NWD | P-sub |
|---|---|---|---|---|---|---|---|---|---|---|---|---|
| Program | 0 V | 5 V | 0 V | 0 V | 8 V | 0 V | 0 V | 5 V | 0 V | 0 V | 0 V | 0 V |
| (hot | | | | | | | | | | | | |
| electron) | | | | | | | | | | | | |
| Program | 0 V | 5 V | 0 V | 0 V | 8 V | 0 V | 0 V | −4 V | 0 V | −4 V | 0.3 V | 0 V |
| (F-N) | | | | | | | | | | | | |
| Erase | 0 V | 0 V | 0 V | 0 V | −8 V | 0 V | 0 V | 5 V | 0 V | 0 V | 0 V | 0 V |
| (F-N) | | | | | | | | | | | | |
| Erase | 0 V | 0 V | 0 V | 0 V | 12 V | 0 V | 0 V | 0 V | 0 V | 0 V | 0 V | 0 V |
| (hot hole) | | | | | | | | | | | | |
| Read | 0 V | 5 V | 0 V | 0 V | 3 V | 0 V | 0 V | 0 V | 1.5 V | 0 V | 0 V | 0 V |

For hot electron programming the nitride gate memory cell NG₁, 5V is applied to WL₁, 5V is applied to BL₁, and 8V is applied to SG₁, thereby an effective high voltage bias is generated, so that electrons can be injected into the nitride gate memory cell NG₁, i.e., hot electron programming occurs.

For F-N programming the nitride gate memory cell NG₁, 5V is applied to WL₁, −4V is applied to BL₁, 8V, −4V and 0.3V are respectively applied to SG₁, PWI and NWD, and P-sub is grounded, thereby an effective high voltage bias is generated, so that electrons can tunnel into the nitride gate memory cell NG₁.

For F-N page erasure, i.e., erasing all the memory cells of a wordline, a negative voltage such as −8V is applied to SG₁, and 5V is applied to BL₁, so as to generate sufficient bias voltage to inject hot holes into the nitride gate memory cell NG₁, thereby effectively naturalizing electrons in the nitride gate memory cell.

For hot hole page erasure, i.e., erasing all the memory cells of a wordline, a positive voltage such as 12V is applied to SG₁ to generate sufficient bias voltage to inject hot holes into the nitride gate memory cell NG₁, thereby effectively naturalizing electrons in the nitride gate memory cell.

For reading, 5V is applied to WL₁, 3V is applied to the SG₁, and 1.5V is applied to BL₂.

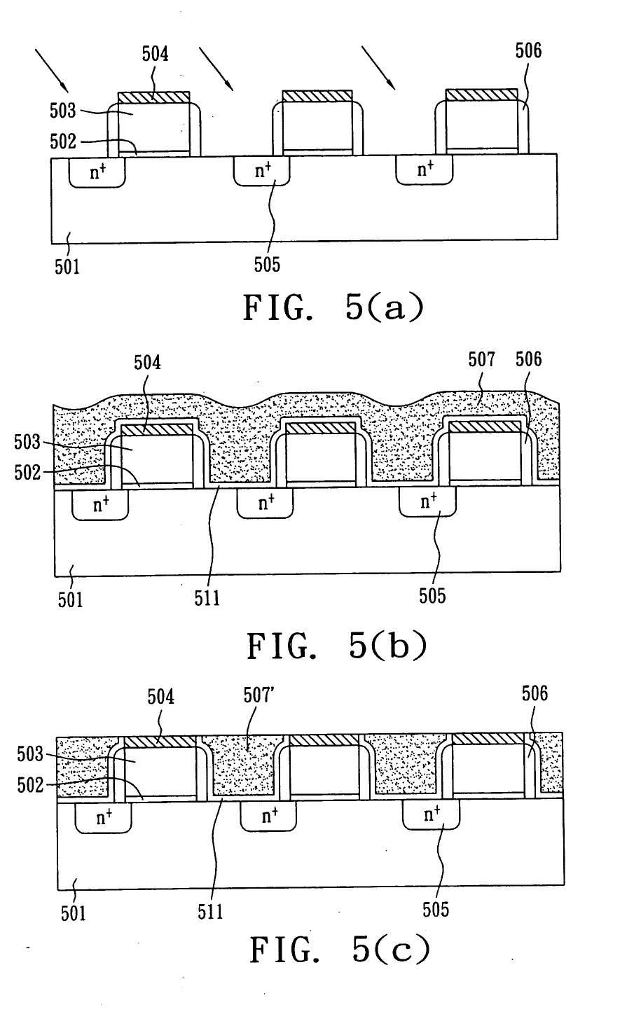

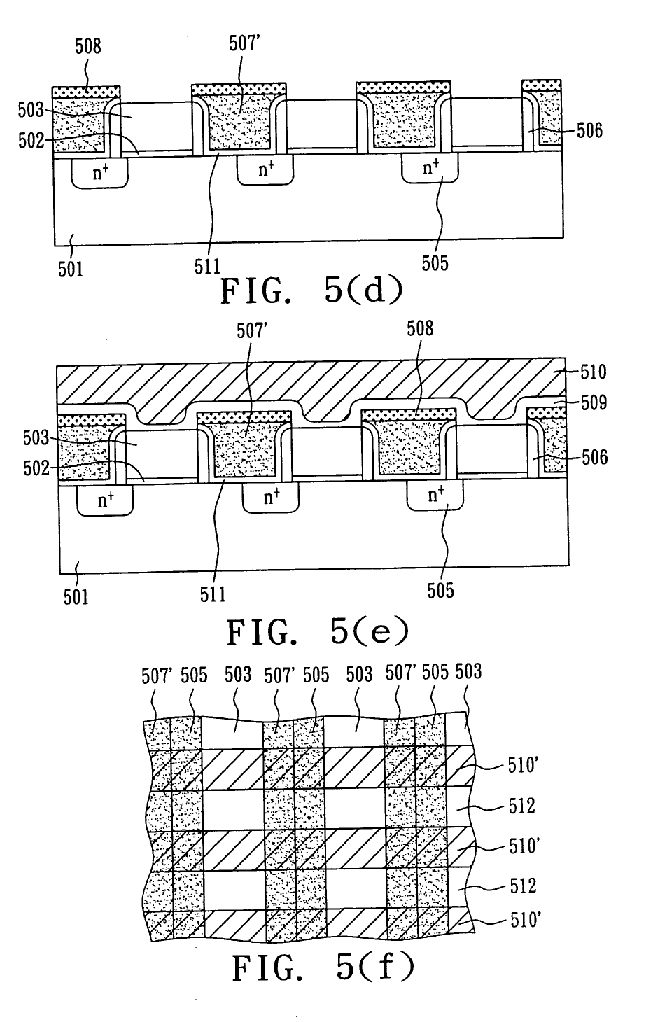

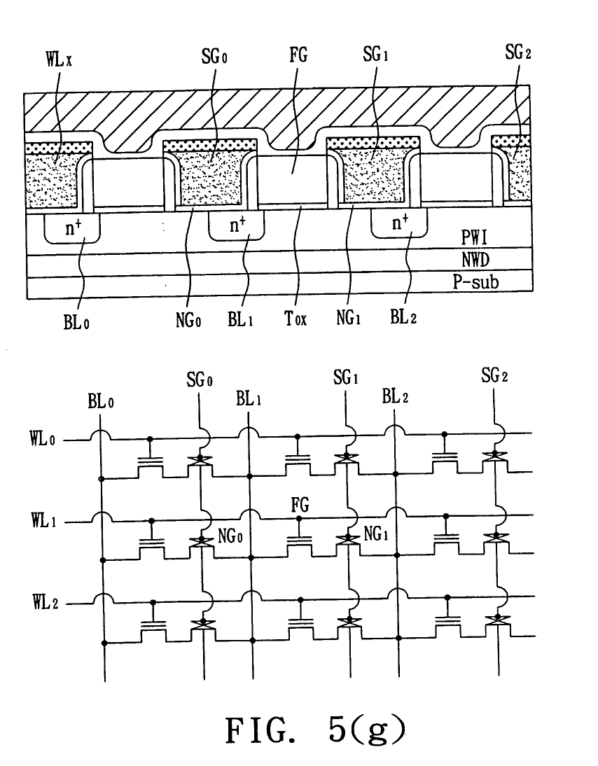

FIGS. 5(a) through 5(f) illustrate a process for forming the memory structure of the second embodiment in accordance with the present invention.

In FIG. 5(a), a gate dielectric layer, a first conductive layer and a silicon nitride layer are sequentially formed on a semiconductor substrate 501, and are patterned to be separated gate structures. Each gate structure comprises a gate dielectric layer 502, a first conductive line 503 and a silicon nitride layer 504, where the gate dielectric layer 502 is in the range of 70 to 150 angstroms, the first conductive line 503 is in the range of 400 to 2000 angstroms, and the silicon nitride layer 504 is in the range of 500 to 2000 angstroms. Then, dielectric spacers 506 ranging from 100 to 300 angstroms are formed beside the two sides of the first conductive line 503, followed by tilt-implanting dopants such as arsenic ions with an energy between 5×10¹⁴ and 5×10¹⁵ atoms/cm², so as to form doping regions 505 serving as bitlines. In FIGS. 5(b) and 5(c), an ONO layer 511 is deposited, and then a conductive layer 507 is deposited and planarized to be second conductive lines 507′. In FIG. 5(d), the silicon nitride layers 504 are removed by, for example, hot phosphoric acid, and then insulating layers 508 such as oxide layers ranging from 800 to 2000 angstroms are formed on the second conductive line 507′ by either thermal growth or deposition. In FIG. 5(e), a second dielectric layer 509, e.g., an ONO layer, and a third conductive layer 510 are formed in order. In FIG. 5(f), illustrating the top view of the memory array, the third conductive layer 510 is patterned to be separated third conductive lines 510′ serving as wordlines, and oxide layers 512 are formed therebetween for insulation. The third conductive lines 510′ are substantially perpendicular to the two doping regions 505. Accordingly, the first and second conductive lines 503 and 507′ function as a floating gate and a select gate, respectively, whereas the ONO layers 511 function as a storage layer, i.e., a nitride gate dielectric, capable of trapping electrons.

Accordingly, there are two bits per cell in a memory cell architecture, i.e., two memory cells including a nitride gate and a floating gate memory cells between two bitlines. Moreover, these two memory cells can also be repetitive between two bitlines, e.g., an NAND structure, without departing from the spirit of the present invention.

FIG. 5(g) illustrates a schematic diagram with reference to the memory structure of the second embodiment set forth in the present invention, in which the memory architecture is the same as that shown in FIG. 5(e) but some components are renamed according to their functionality as mentioned in the first embodiment. The memory structure shown in FIG. 5(g) is quite similar to that shown in FIG. 4(g) except that positions of select gate and floating gate are interchanged. Because the operation method for memory cells as shown in FIG. 5(g) are essentially equivalent to that mentioned in the first embodiment, they are omitted herein.

In addition to the application to a non-volatile memory cell of NMOS type as the above mentioned, a memory cell of PMOS type can also be implemented without departing from the spirit of the present invention.

The above-described embodiments of the present invention are intended to be illustrative only. Numerous alternative embodiments may be devised by those skilled in the art without departing from the scope of the following claims.

What is claimed is:

1. A memory structure on a semiconductor substrate, comprising:
two bitlines formed in the semiconductor substrate;
a floating gate formed above the semiconductor substrate;
a select gate formed above the semiconductor substrate; and
a nitride gate dielectric formed between the select gate and the semiconductor substrate;
wherein the floating gate and the select gate are transversely disposed between the two bitlines, and the floating gate and nitride gate dielectric function as two memory cells.

2. The memory structure in accordance with claim 1, further comprising a wordline formed above the floating gate and the select gate.

3. The memory structure in accordance with claim 2, further comprising an oxide/nitride/oxide layer formed between the wordline and the floating gate.

4. The memory structure in accordance with claim 2, further comprising an insulating layer formed between the select gate and the wordline.

5. The memory structure in accordance with claim 1, wherein the floating gate and select gate are composed of polysilicon.

6. The memory structure in accordance with claim 1, wherein the nitride gate dielectric is an oxide/nitride/oxide layer.

7. A method for manufacturing a memory structure, comprising the steps of:
providing a semiconductor substrate;
forming a storage layer on the semiconductor substrate;
forming a first conductive line above the storage layer;
forming at least one dielectric spacer beside the first conductive line;
forming two doping regions in the semiconductor substrate;
forming a first dielectric layer on the doping regions and the semiconductor substrate;
forming a second conductive line on the first dielectric layer;
forming a second dielectric layer above the first and second conductive lines; and
forming a third conductive line on the second dielectric layer, wherein the third conductive line is substantially perpendicular to the two doping regions;
wherein the first and second conductive lines are transversely disposed between the two doping regions, and the dielectric spacer is between the first and second conductive lines.

8. The method for manufacturing a memory structure in accordance with claim 7, wherein the doping region is formed by the steps of:
forming a mask spacer beside the dielectric spacer; and
implanting dopants into the semiconductor substrate uncovered by the mask spacer.

9. The method for manufacturing a memory structure in accordance with claim 8, wherein the mask spacer is removed before the first dielectric layer forms.

10. The method for manufacturing a memory structure in accordance with claim 8, wherein the mask spacer is formed by the steps of:
forming two mask spacers beside the two sides of the first conductive line;
capping one of the mask spacers by photoresist;
removing the other mask spacer; and
removing the photoresist.

11. The method for manufacturing a memory structure in accordance with claim 7, wherein the first and second conductive lines are composed of polysilicon.

12. The method for manufacturing a memory structure in accordance with claim 7, wherein the storage layer is an oxide/nitride/oxide layer.

13. The method for manufacturing a memory structure in accordance with claim 7, wherein the second dielectric layer is an oxide/nitride/oxide layer.

14. The method for manufacturing a memory structure in accordance with claim 7, wherein the first dielectric is formed by thermal growth, and the portion of the first dielectric layer on the doping regions is thicker than that on the semiconductor substrate.

15. The method for manufacturing a memory structure in accordance with claim 7, further comprising the step of forming an insulating layer on the first conductive line.

16. A method for manufacturing a memory structure, comprising the steps of:
providing a semiconductor substrate;
forming a first conductive line above the semiconductor substrate;
forming at least one dielectric spacer beside the first conductive line;
forming two doping regions in the semiconductor substrate;
forming a first dielectric layer including at least one nitride film on the semiconductor substrate;
forming a second conductive line on the first dielectric layer;
forming an insulating layer on the second conductive line;
forming a second dielectric layer on the first conductive line and the insulating layer; and
forming a third conductive line on the second dielectric layer, wherein the third conductive line is substantially perpendicular to the two doping regions;
wherein the first and second conductive lines are transversely disposed between the two doping regions, and the dielectric spacer is formed between the first and second conductive lines.

17. The method for manufacturing a memory structure in accordance with claim 16, wherein the two doping regions are formed by implanting dopants with a tilted angle.

18. The method for manufacturing a memory structure in accordance with claim 16, wherein the first and second conductive lines are composed of polysilicon.

19. The method for manufacturing a memory cell in accordance with claim 16, wherein the second dielectric layer is an oxide/nitride/oxide layer.

20. A method for programming a memory structure, comprising the steps of:
providing a memory structure formed on a semiconductor substrate of a first conductive type and having two bitlines of a second conductive type, a select gate, a floating gate, a storage layer, a wordline and a dielectric layer, wherein the select gate and floating gate are transversely disposed between the two bitlines and insulated by a dielectric spacer therebetween, the storage layer is between the select gate and the semiconductor substrate, the dielectric layer is between the floating gate and the semiconductor substrate, and the wordline is above the select gate and floating gate;
applying a positive voltage to the wordline so as to turn on the floating gate; and
applying a negative voltage to the bitline next to the floating gate;
whereby a bias voltage across the dielectric layer is generated for programming the floating gate.

21. The method for programming a memory structure in accordance with claim 20, further comprising the step of applying a negative voltage to another select gate next to the floating gate.

22. The method for programming a memory structure in accordance with claim 21, wherein the absolute value of the negative voltage applied to the select gate is equal to or larger than that of the negative voltage applied to the bitline next to the floating gate.

23. The method for programming a memory structure in accordance with claim 20, wherein the semiconductor substrate comprises a first well of the first conductive type and a second well of the second conductive type, the two bitlines are formed within the first well, and the first well is surrounded by the second well.

24. The method for programming a memory structure in accordance with claim 23, wherein a negative voltage and a positive voltage are applied to the first well and the second well respectively, the absolute value of the negative voltage applied to the first well is equal to or larger than that of the negative voltage applied to the bitline next to the floating gate, and the semiconductor substrate is grounded.

25. A method for programming a memory structure, comprising the steps of:
providing a memory structure formed on a semiconductor substrate of a first conductive type and having two bitlines of a second conductive type, a select gate, a floating gate, a storage layer, a wordline and a dielectric layer, wherein the select gate and floating gate are transversely disposed between the two bitlines and insulated by a dielectric spacer therebetween, the storage layer is between the select gate and the semiconductor substrate, the dielectric layer is between the floating gate and the semiconductor substrate, and the wordline is above the select gate and floating gate;
applying a positive voltage to the wordline, so as to turn on the floating gate;
applying a positive voltage to the select gate, so as to turn on the select gate; and
applying a positive voltage to the bitline next to the storage layer;
whereby a bias voltage between the two bitlines is generated for programming the storage layer.

26. A method for programming a memory structure, comprising the steps of:
providing a memory structure formed on a semiconductor substrate of a first conductive type and having two bitlines of a second conductive type, a select gate, a floating gate, a storage layer, a wordline and a dielectric layer, wherein the select gate and floating gate are transversely disposed between the two bitlines and insulated by a dielectric spacer therebetween, the storage layer is between the select gate and the semiconductor substrate, the dielectric layer is between the floating gate and the semiconductor substrate, and the wordline is above the select gate and floating gate;
applying a positive voltage to the wordline, so as to turn on the floating gate;
applying a positive voltage to the select gate, so as to turn on the select gate; and
applying a negative voltage to the bitline next to the floating gate;
whereby a bias voltage between the storage layer is generated for programming the storage layer.
